(19) United States
(12) Patent Application Publication
(10) Pub. No.: US 2013/0222982 A1
(43) Pub. Date: Aug. 29, 2013

(54) ELECTRONIC DEVICE HAVING SENSOR WINDOW COVER

(71) Applicant: HONG LI, Shenzhen City (CN)

(72) Inventor: HONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/532,846

(22) Filed: Jun. 26, 2012

(30) Foreign Application Priority Data
Feb. 29, 2012 (CN) 201210049264.7

(51) Int. Cl. H05K 5/02

(52) U.S. Cl. 361/679.01

(57) ABSTRACT

An electronic device includes a housing having a first sidewall defining an opening, a signal receiving unit, and a sensor window cover corresponding the signal receiving unit and defining at least one latching groove. Two latching members and at least one block are secured to an inner surface of the first sidewall. The latching members abut the sensor window cover against the inner surface of the first sidewall to prevent the sensor window from moving in a first direction perpendicular to the first sidewall, and the at least one block is latched to the at least one latching groove to prevent the sensor window from disengaging with the housing in a second direction perpendicular to the first direction.

### BACKGROUND

1. Technical Field

The present disclosure relates to electronic devices, and particularly to an electronic device having a sensor window cover.

2. Description of Related Art

Electronic devices, such as DVD players, may include a housing and a sensor window cover secured to the housing. The sensor window cover includes a hook member. The housing defines an area to be covered by the sensor window cover, and includes a latching member arranged adjacent to the area. The latching member corresponds to the hook member and hooks the hook member to secure the sensor window cover to the housing. However, if the sensor window cover is made of polymethyl methacrylate, the sensor window cover may be easily broken when being secured to the housing.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the five views.

FIG. 1 is a partial perspective view of an electronic device having a sensor window cover in accordance with an embodiment.

FIG. 2 is a partially enlarged view of the electronic device of FIG. 1.

FIG. 3 is a disassembled view of the electronic device of FIG. 2.

FIG. 4 is similar to FIG. 3, but viewed from another aspect.

FIG. 5 is a partial cross-sectional view taken along line V-V in FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

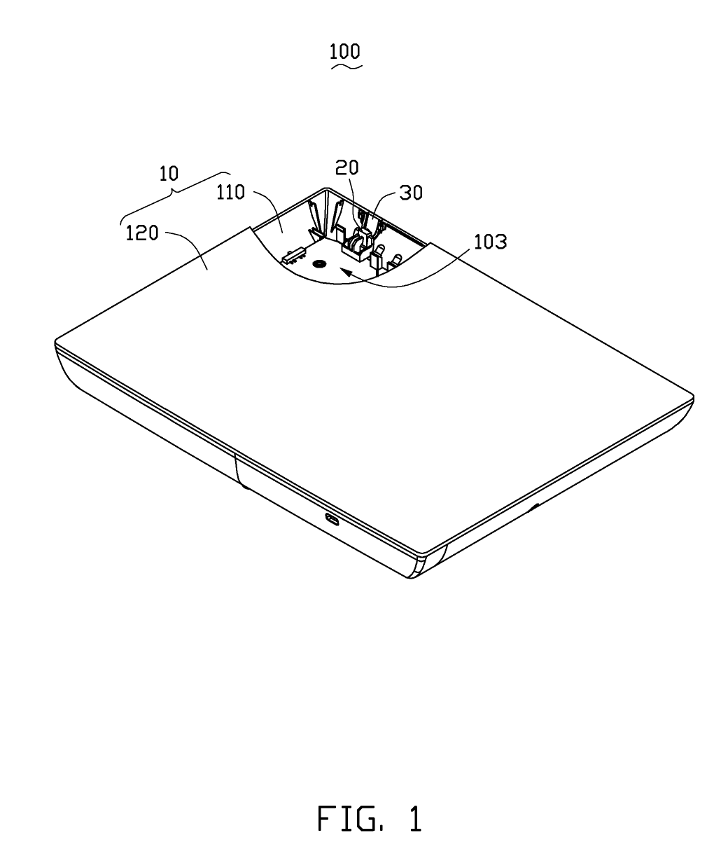

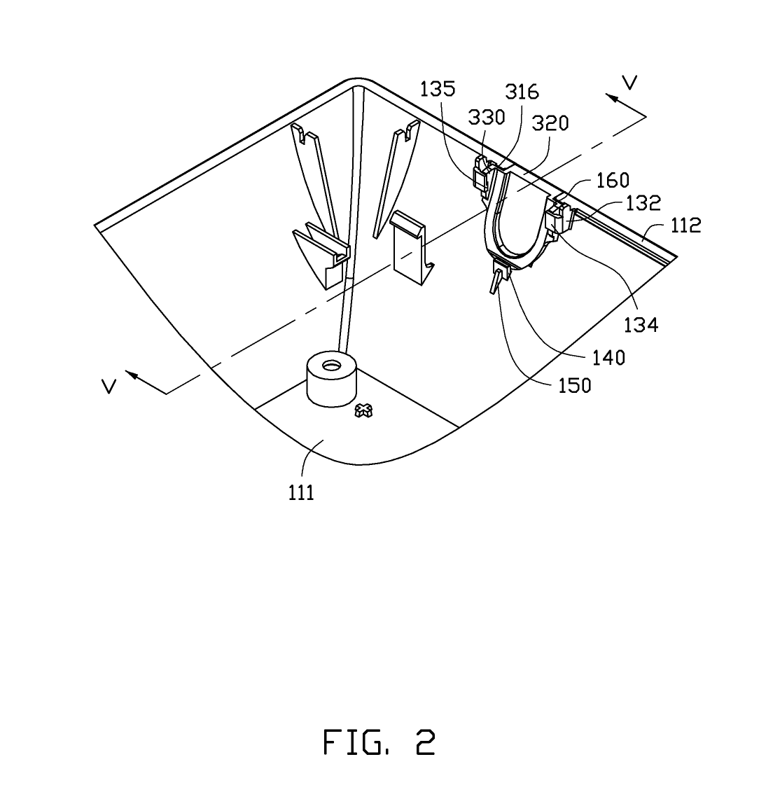

Referring to FIGS. 1-2, an electronic device 100 having a sensor window cover 30 is shown. The electronic device 100 includes a housing 10, a signal receiving unit 20 received in the housing 10, and a sensor window cover 30 secured to the housing 10 and corresponding to the signal receiving unit 20. The electronic device 100 in the embodiment is a DVD player.

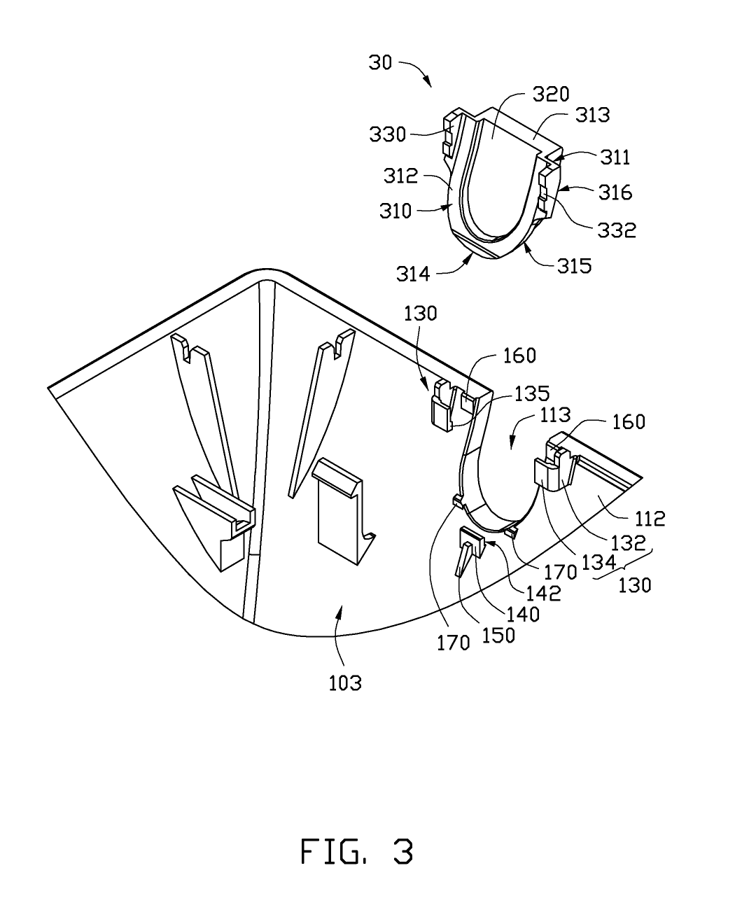

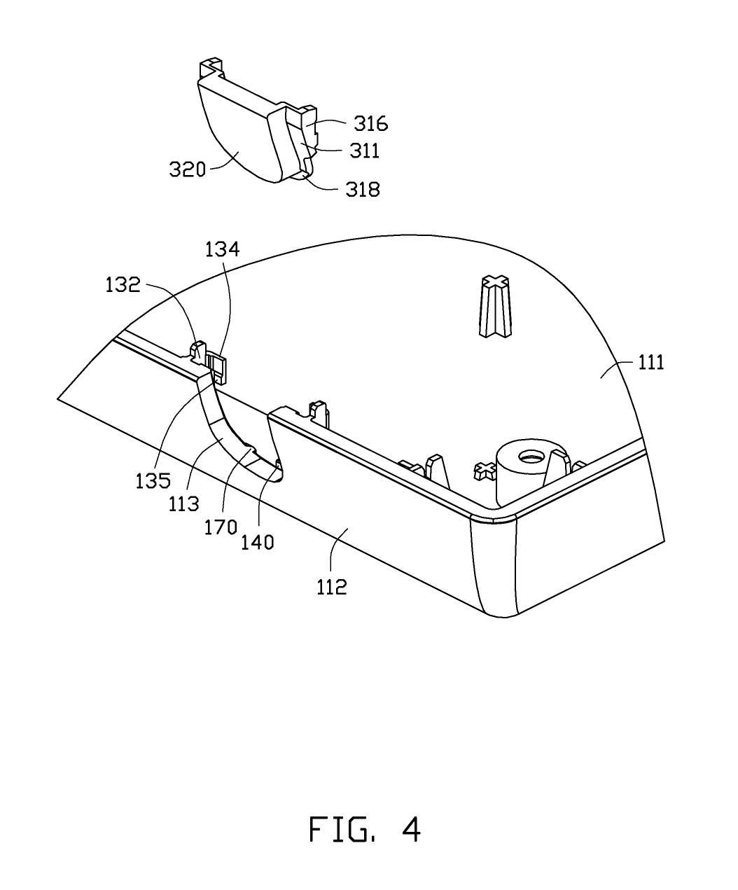

Referring to FIGS. 3-4, the sensor window cover 30 includes a base 310, a window 320 secured to the base 30, and two latching portions 330 arranged at opposite ends of the base 310. The latching portions 330 and the window 320 extend from opposite sides of the base 310 in opposite directions. The base 310 is substantially U-shaped. The base 310 includes an outer surface 311, an inner surface 312 opposite to the outer surface 311, a first end 313, a second end 314 opposite to the first end 313, and opposite side ends 315.

The window 320 is substantially U-shaped, and is made of polymethyl methacrylate in the embodiment. The window 320 is secured to the outer surface 311 of the base 310 with an end being coplanar with the first end 313. The size of the window 320 is less than the size of the base 310, for forming a substantially U-shaped stepper 316. When viewed from the outer surface 311 of the base 310, the window 320 protrudes out of the outer surface 311 of the base 310; when viewed from the inner surface 312 of the base 310, the window 320 is recessed in the inner surface 312 of the base 310. An end of the stepper 316 away from the latching portions 330 further defines two latching grooves 318. The latching grooves 318 are arranged at opposite sides of the window 320 and are adjacent to the second end 314.

The latching portions 330 perpendicularly extend from the side ends 315 respectively and are coplanar with the first end 313. Each latching portion 330 is substantially triangular. The height of each latching portion 330 relative to the base 310 decreases from an end coplanar with the first end 313. An end of each latching portion 330 opposite the window 320 defines a recess 332.

Referring again to FIGS. 2 and 3, the housing 10 includes a bottom case 110 and a top case 120. The top case 120 engages with the bottom case 110 to define a receiving space 103 (FIG. 1) for receiving a circuit board, a power supply, and other components (not shown) of the electronic device 100.

The bottom case 110 includes a bottom wall 111 and four sidewalls protruding from the rims of the bottom wall 111. One of the sidewalls being in front of the electronic device 100 is referred to herein as the first sidewall 112. The first sidewall 112 defines an opening 113 (FIG. 3). The opening 113 is substantially U-shaped, and corresponds to the signal receiving unit 20. The opening 113 is used to receive the window 320. In the embodiment, the size of the opening 113 corresponds with the size of the window 320, such that the window 320 is a close fit in the opening 113.

Two latching members 130 are made of elastic material, and are secured to an inner surface of the first sidewall 112. The latching members 130 are arranged at opposite sides of the opening 113. Each latching member 130 includes a connecting portion 132 and a hook portion 134. The connecting portion 132 perpendicularly extends from the inner surface of the first sidewall 112. The distance between the connecting portions 132 is slightly larger than the distance between the latching portions 330. The hook portions 134 perpendicularly bend from ends of the connecting potions 132 away from the first sidewall 112 and extend toward each other. A protrusion 135 protrudes from a surface of each hook portion 134 facing the first sidewall 112. The distance between the protrusions 135 and the first sidewall 112 is substantially equal to the distance between the recess 332 and the outer surface 311.

An abutting member 140 is secured to the inner surface of the first sidewall 112. The abutting member 140 is arranged adjacent to the bottom of the opening 113. The abutting member 140 and the latching members 130 are arranged in a triangular shape. In the embodiment, the abutting member 140 is between and equidistance from the latching members 130. A clipping space 142 is defined between the abutting member 140 and the first sidewall 112. The clipping space 142 is used for clipping the second end 312 of the base 310. A rib 150 is secured to the abutting member 140 and connects with the inner surface of first sidewall 112 to enhance the stiffness of the abutting member 140.

Two guiding members 160 protrude from the inner surface of the first sidewall 112. The guiding members 160 are used for guiding the sensor window cover 30 to be secured to the bottom case 110. The guiding members 160 are arranged on opposite sides of the opening 113 and are sandwiched between the connecting portions 132. Furthermore, two blocks 170 protrude from the inner surface of the first wall 112. The blocks 170 are arranged at opposite sides of the opening 113 and are capable of being received in and latched to the latching grooves 318 respectively.

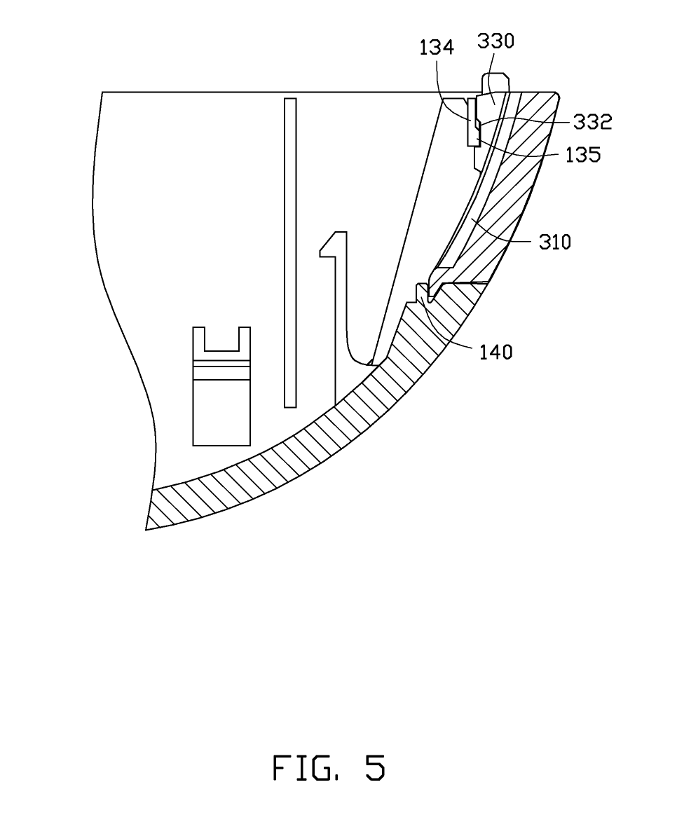

Referring to FIGS. 2 and 5, in assembly, firstly, the second end 312 of the base 310 is inserted between the connecting portions 132, and the window 320 is aligned with the opening 113. Secondly, the base 310 is pressed down, the window 320 is close fit in the opening 113, at the same time, the latching members 130 elastically deform, such that the protrusions 315 are latched to the recesses 332, and the blocks 170 are latched to the latching grooves 318. As a result, the sensor window cover 30 is secured to the bottom case 110.

When assembled, because the stepper 316 abuts the inner surface of the first sidewall 112 and the hooking portions 134 clip the latching portions 330, the sensor window cover 30 is prevented from moving in a first direction perpendicular to the first sidewall 112. Furthermore, the protrusions 135 are latched to the recesses 332, and the blocks 170 are latched to the latching grooves 318, thus, the sensor window cover 30 is prevented from disengaging with the bottom case 110 in a second direction perpendicular to the bottom wall 111. As a result, the sensor window cover 30 is steadily secured to the housing 10 and is further prevented from loosening.

It is to be understood, even though information as to, and advantages of, the present embodiments have been set forth in the foregoing description, together with details of the structures and functions of the present embodiments, the disclosure is illustrative only; and that changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a housing having a first sidewall, the first sidewall defining an opening;
a signal receiving unit received in the housing; and
a sensor window cover secured to the first sidewall and corresponding to the signal receiving unit, the sensor window cover comprising a base and a window secured to the base and capable of being received in the opening, the base defining at least one latching groove;
wherein two latching members and at least one block are secured to an inner surface of the first sidewall; the latching members abut the base against the inner surface of the first sidewall to prevent the sensor window from moving in a first direction perpendicular to the first sidewall, and the at least one block is latched to the at least one latching groove to prevent the sensor window from disengaging with the housing in a second direction perpendicular to the first direction.

2. The electronic device of claim 1, wherein the base includes a first surface and a second surface opposite to the first surface, the window is secured to the first surface, and at least one latching groove is defined at the first surface.

3. The electronic device of claim 2, wherein the size of the base is greater than the size of the window, for forming a stepper, the stepper abuts the inner surface of the first sidewall when the sensor window cover is secured to the housing.

4. The electronic device of claim 1, wherein two latching portions are secured to opposite sidewalls of the base and correspond to the latching members respectively, the latching portions and the window extend from opposite sides of the base in opposite directions.

5. The electronic device of claim 4, wherein each latching member comprises a connecting portion perpendicularly extending from the first sidewall and a hook portion secured to an end of the connecting portion away form the first sidewall.

6. The electronic device of claim 5, wherein the distance between the connecting portions is slightly greater than the distance between the latching portions.

7. The electronic device of claim 5, wherein the hook portions respectively abut the latching portions to make the base abut against the inner surface of the window.

8. The electronic device of claim 5, wherein each latching portion defines a recess, a protrusion is secured to a surface of the hook portion facing the first sidewall and corresponding to the recess, the protrusion is latched to the recess when the sensor window cover is secured to the housing.

9. The electronic device of claim 8, wherein the distance between the protrusion and the first sidewall is substantially equal to the distance between the recess and a surface of the base where the window is secured.

10. The electronic device of claim 1, wherein the latching members are made of elastic material.

11. The electronic device of claim 1, wherein an abutting member is secured to an inner surface of the first sidewall, the abutting member is used to clip an end of the base.

12. The electronic device of claim 11, wherein the abutting member is between and equidistant from the latching members.
